(19) United States
(12) Patent Application Publication
(10) Pub. No.: US 2011/0012257 A1
(43) Pub. Date: Jan. 20, 2011

(54) HEAT SPREADER FOR SEMICONDUCTOR PACKAGE

(75) Inventors: Poh Leng EU, Petaling Jaya (MY); Ruzaini Ibrahim, Bandar Puncak Alam (MY); Kar Wei Shim, Petaling Jaya (MY); Kai Yun Yow, Petaling Jaya (MY)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC, Austin, TX (US)

(21) Appl. No.: 12/503,056

(22) Filed: Jul. 14, 2009

(51) Int. Cl. H01L 23/34; H01L 23/36; H01L 23/16

(52) U.S. Cl. 257/713; 257/712; 257/E23.08; 257/E23.101; 257/E23.135

(57) ABSTRACT

A semiconductor package including a substrate, a die attached to the substrate and a heat spreader. The heat spreader has a heat dissipating portion with an upper surface, a lower surface and a perimeter. The lower surface overlies and is spaced apart from the die to provide a clearance therebetween. Supports are spaced about the perimeter of the heat dissipating portion and depend downwardly therefrom. Each support is located on the substrate to establish an opening between adjacent supports.

### BACKGROUND OF THE INVENTION

The present invention relates to semiconductor packages, and more specifically to ball grid array packages with heat spreaders, such as a thermally enhanced ball grid array.

A semiconductor package includes a semiconductor die that is attached to a substrate and wire bonded to connection points on the substrate to form electrical connections with contacts that may be soldered to a printed circuit board (PCB). The die is encapsulated in an encapsulant material, such as a thermosetting resin mold compound, to provide protection to the die and the electrical interconnections.

During operation of the semiconductor package, heat generated by the die must be removed to ensure correct operation of the die. To assist with heat removal, some semiconductor packages incorporate a heat spreader that is typically encapsulated in the mold compound.

One example of a conventional semiconductor package is described in U.S. Pat. No. 7,126,218. U.S. Pat. No. 7,126,218 describes a semiconductor package that includes a heat spreader attached directly to an upper surface of a ball grid array package with a thin adhesive layer. The shape of the heat spreader conforms to the topographical profile of the underlying die. According to U.S. Pat. No. 7,126,218, attaching the heat spreader directly to the die results in a very low thermal resistance at the interface between the die and the heat spreader. However, directly attaching the heat spreader to the die may obstruct plasma cleaning (prior to molding) and also obstruct mold flow of the mold compound during a side gate molding process. Obstruction of plasma cleaning may have the undesirable result of reducing the effectiveness of the cleaning process and thus also reduce mold compound adhesion. Obstruction of the mold flow may result in unbalanced mold flow.

It is believed that reducing the effectiveness and unbalanced mold flow may contribute to delamination of either the heat spreader or the die from the substrate. Accordingly, it would be desirable to have a heat spreader the does not impair mold flow or plasma cleaning for a side gate molding process.

### BRIEF DESCRIPTION OF THE DRAWINGS

The present invention will now be described in relation to preferred embodiments as illustrated in the accompanying drawings. However, it is to be understood that the following description is not to limit the generality of the above description.

FIG. 1 is a top view of a semiconductor package according to an embodiment of the present invention;

FIG. 2 is a side sectional view of the semiconductor package of FIG. 1 along sectional line A-A′;

FIG. 3 is an enlarged sectional view of the region “B” of the semiconductor package of FIG. 2;

FIG. 4 is a top view of the heat spreader incorporated in the semiconductor package of FIG. 1;

FIG. 5 is a side sectional view of the heat spreader package of FIG. 5 along sectional line D-D′ of FIG. 4;

FIG. 6 is a side view of the semiconductor package of FIG. 1 along line C-C′;

FIG. 7 is a top view of another embodiment of a heat spreader suitable for incorporating in the semiconductor package of FIG. 1;

FIG. 8 is a side view of the heat spreader of FIG. 7 taken along sectional line F-F′ of FIG. 7;

FIG. 9A to FIG. 9C show an example of a method of locating the heat spreader of FIG. 7 onto a substrate;

FIG. 10 shows an alternative arrangement for locating the heat spreader of FIG. 7 onto a substrate;

FIG. 11 is a diagram depicting mold flow paths for a side gate molding process;

FIG. 12 is a diagram depicting mold flow timing and distribution for a side gate molding process;

FIG. 13 is a top view of another embodiment of a heat spreader suitable for incorporating in the semiconductor package of FIG. 1; and

FIG. 14 is a side view of the heat spreader of FIG. 13 taken along sectional line G-G′ of FIG. 13

### DETAILED DESCRIPTION OF AN EMBODIMENT

The present invention provides a semiconductor package that incorporates a heat spreader configured to provide improved mold flow and cleaning processes during manufacture of the semiconductor package.

In one aspect the present invention provides a semiconductor package, comprising a substrate, a die attached to substrate and a heat spreader. The heat spreader comprises a heat dissipating portion comprising an upper surface, a lower surface and a perimeter. The lower surface overlies and is spaced apart from the die to provide a clearance therebetween. Plural supports are spaced about the perimeter of the heat dissipating portion and depend downwardly thereof. Each support is located on the substrate to establish an opening between adjacent supports.

In an embodiment, the upper surface of the heat dissipating portion is exposed and thus not covered by the encapsulant. Not covering the upper surface of the heat dissipating portion with encapsulant may enhance the thermal conductivity of the heat spreader and thus provide an improved ability to remove heat from the die.

Each opening will provide a vertical extent which extends between the lower surface of the heat dissipating portion and the substrate, and a horizontal extent which extends extending between opposite side edges of the adjacent supports. The horizontal and vertical extents are adapted to permit flow of a molding compound through the openings to encapsulate the die and fill the clearance. The openings also permit plasma cleaning of the die prior to the encapsulation.

The supports may be uniformly spaced about the perimeter of the heat dissipating portion. In an embodiment, each support subtends a central angle δ about a respective extent of the perimeter of the heat dissipating portion. It is preferred that each opening subtends a central angle θ about a respective extent of the perimeter of the heat dissipating portion which is substantially the same as or greater than the central angle δ. Furthermore, at each opening it is preferred that the heat spreader has a peripheral or outermost extent which corresponds with the perimeter of the heat dissipating portion.

The present invention also provides a plastic ball grid array semiconductor package, comprising a substrate, a die attached to substrate and a heat spreader. The heat spreader comprises a heat dissipating portion comprising an upper surface, a lower surface and a perimeter. The lower surface overlies and is spaced apart from the die to provide a clearance therebetween. Plural supports spaced about the perimeter of the heat dissipating portion and depend downwardly thereof. Each support is located on the substrate to establish an opening between adjacent supports. Each opening has a vertical extent which extends between the lower surface of the heat dissipating portion and the substrate, and a horizontal extent which extends between opposite side edges of the adjacent supports.

The vertical extent and the horizontal extent of the openings are adapted for flow therethough of a molding compound for filling the clearance and encapsulating the die.

The present invention also provides a method of packaging a semiconductor die, comprising providing a substrate, attaching the die to the substrate, attaching a heat spreader to the substrate. The heat spreader comprises a heat dissipating portion comprising an upper surface, a lower surface and a perimeter. The lower surface overlies and is spaced apart from the die to provide a clearance therebetween. Plural supports are spaced about the perimeter of the heat dissipating portion and depend downwardly thereof. Each support is located on the substrate to establish an opening between adjacent supports. After the heat spreader has been attached to the substrate a molding compound is injected to flow through the openings to fill the clearance and encapsulate the die.

The present invention also provides a heat spreader for attaching to a substrate of a semiconductor package, the heat spreader comprising a heat dissipating portion comprising an upper surface, a lower surface and a perimeter. Plural supports are spaced about the perimeter of the heat dissipating portion and depend downwardly thereof. Each support is adapted to locate the heat spreader on the substrate to establish an opening between adjacent supports, such that each opening has a vertical extent extending between the lower surface of the heat dissipating portion and the substrate and a horizontal extent extending between opposite side edges of the adjacent supports. The vertical extent and the horizontal extent of the openings are adapted for flow therethough of a molding compound, said molding compound for filling the clearance and encapsulating the die.

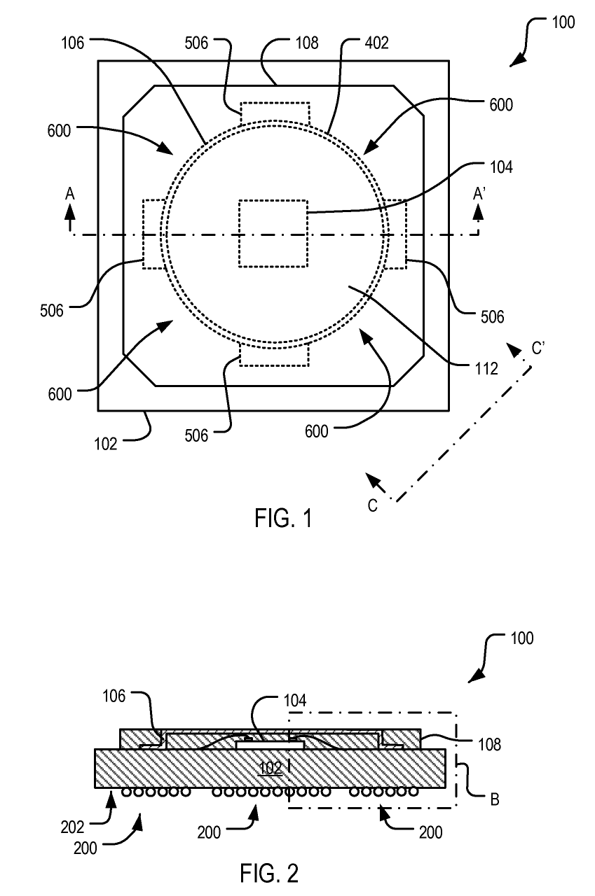

Referring now to FIG. 1 and FIG. 2, a semiconductor package 100 according to an embodiment of the present invention includes a substrate 102, a die 104 attached to the substrate 102 (ref. FIG. 2), a heat spreader 106, and an encapsulant 108 in the form of a molding compound.

The semiconductor package 100 is illustrated as a thermally enhanced plastic ball grid array (TEPGA) device. However, although the following embodiment relates to a TEPGA device, it will be appreciated that a heat spreader according to an embodiment may be used in other type of semiconductor devices which are manufactured using a process that involves “over molding”, such as side gate molding, of the encapsulant 108.

The substrate 102 provides the semiconductor package 100 with a base for mechanically supporting the die 104 and also provides an electrical interface for forming suitable electrical connections with the die 104. Typically, the electrical connections are formed using interconnecting elements, such as wires, which are connected by way of a suitable connection process between an electrically conductive terminal, such as a die pad, disposed on the die 104, and an electrically conductive terminal, which may also be a pad, disposed on the substrate 102. The wires may be made of, for example, gold (Au), copper (Cu), aluminium (Al) or other suitable conductive materials. Suitable connection processes would be well known to a skilled addressee.

The substrate 102 will typically be a laminated structure comprising multiple layers (not shown). The layers preferably include power and ground planes, and one or more planes of a highly thermal conductive material, such as copper, to assist with dissipating heat from the die. Suitable substrate structures including layer arrangements would be well known to a skilled addressee.

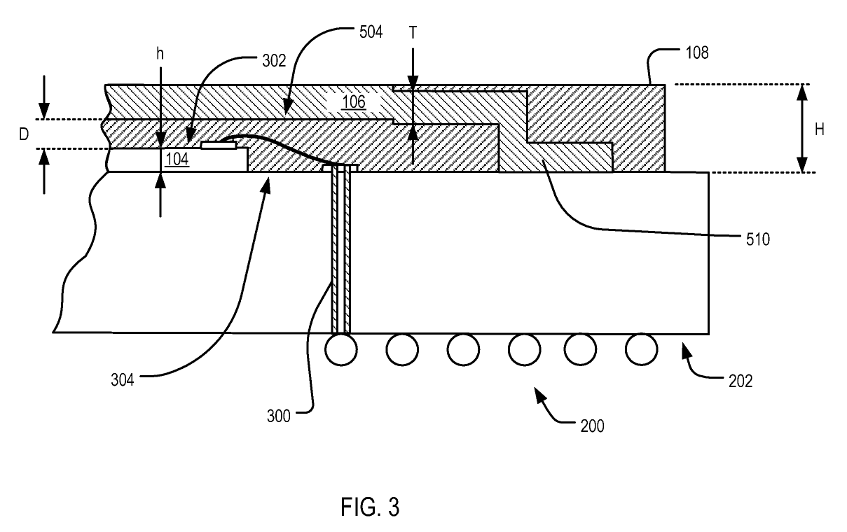

FIG. 2 is a cross sectional view along sectional line A-A′ of FIG. 1. FIG. 3 is an enlarged cross-sectional view of the dashed region ‘B’ identified in FIG. 2.

Referring initially to FIG. 2, the illustrated substrate 102 includes plural preformed solder balls 200 disposed on a lower surface 202 of the substrate 102. The solder balls 200 are in electrical connection with electrical conductors (not shown) of the substrate 102 and allow connection of the semiconductor package 100 to a circuit board during a reflow process.

As shown in FIG. 3, vias, such as via 300, provide through connections between the electrically conductive terminals disposed on the upper surface 304 of the substrate 102 and electrically conductive terminals (not shown) disposed on the lower surface 202 of the substrate 102, with the latter electrically conductive terminals contacting the solder balls 200.

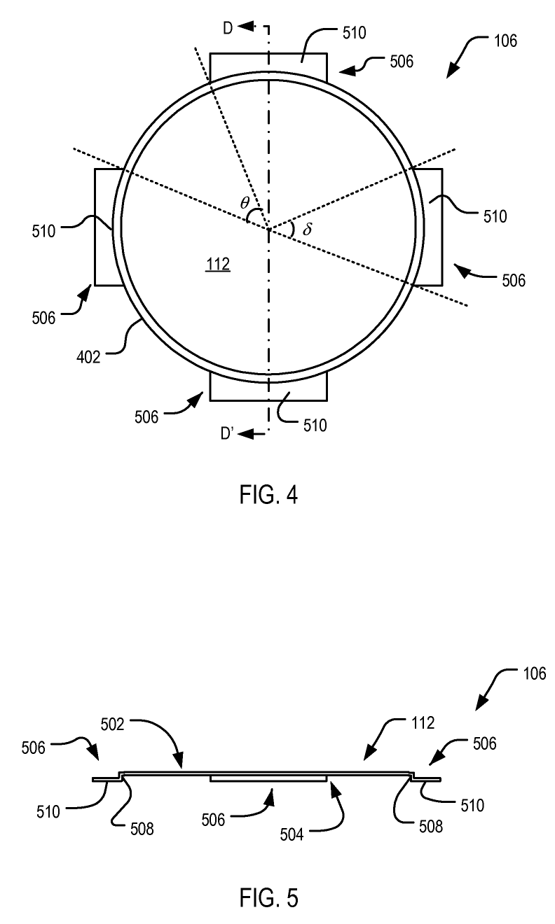

FIG. 4 and FIG. 5 provide a top view and a side view respectively of the heat spreader 106 incorporated in the semiconductor packaged depicted in FIG. 1 to FIG. 3. The heat spreader 106 is formed of a material having high thermal conductivity so that heat generated by the die 104 may be conducted, and thus dissipated, by the heat spreader 106.

The heat spreader 106 may be manufactured by a conventional process, such as, stamping and forming, etching, mechanical cutting, laser cutting or the like. Other suitable manufacturing processes would be well known to a skilled addressee. The heat spreader 106 material may be copper or another highly thermal conductive material could also be used. An example of a suitable material is copper alloy C1100 3/4H with a material thickness of 0.30 mm. Other suitable materials may include, for example, aluminium, silver, or other materials having suitable thermal conductivity properties. A suitable thermal conductivity in the range of about 350 to 400 W/m.K will be suitable.

As shown in FIG. 5, the heat spreader 106 includes a heat dissipating portion 112, comprising an upper surface 502, a lower surface 504, and a perimeter 402 (ref. FIG. 4). In the illustrated embodiment the heat dissipating portion 112 is a planar disc. However it will be appreciated that the shape of the heat dissipating portion 112 may vary according to packaging requirements.

The heat spreader 106 includes plural supports 506 which are connected to or integrally formed with the heat dissipating portion 112. The supports 506 are spaced about the perimeter 402 of the dissipating portion 112 and depend downwardly therefrom to retain the heat dissipating portion 112 in use above the die 104 and thus provide a clearance D therebetween.

In the heat spreader 106 depicted in FIG. 4 and FIG. 5 the supports 506 are each disposed along a respective circumferential extent of the perimeter 402 of the heat dissipating portion 112 to subtend a first central angle (δ). Circumferentially adjacent supports 506 are spaced apart by a circumferential extent which extends about the perimeter 402 to subtend a second central angle (θ), which is also a central angle.

In the present case, the first central angle δ is about forty-four degrees and the second central angle θ is about forty-six degrees. However, it will of course be appreciated that the circumferential extent of each support 506 and the spacing between circumferentially adjacent supports 506 may vary. Indeed, the above configuration and spacing of the spaced apart supports 506 is only one example of a possible configuration and thus other configurations and spacings may also be suitable. Moreover, although in the embodiment illustrated the supports 506 have a uniform width and uniform spacing, it is possible that the width of the supports 506 and/or the spacing therebetween may be non-uniform.

As shown in FIG. 5, each support 506 includes a leg 508 and a base or foot 510 that is adapted for location on the substrate 102 using a suitable bonding process. Suitable bonding processes would be well known to a skilled addressee.

In the embodiment illustrated, each leg 508 depends downwardly (that is, in the direction of the substrate 102) from the perimeter 402 of the heat dissipating portion 112 at a right angle relative to the plane of the upper surface 502 of the heat dissipating portion 112. However, it is possible that each leg 508 may form an acute angle relative to the upper surface 502 of the heat dissipating portion 112.

In the heat spreader 106 illustrated in FIG. 4 to FIG. 5, each base or foot 510 comprises a substantially planar portion having a width and height sized to provide a suitable surface area for attaching to the substrate 102.

Referring now to FIG. 3, each foot 510 is attached to the substrate 102 so as to be disposed upon the upper surface 304 thereof. However, it is to be appreciated that it is not essential that each foot 510 be disposed upon the upper surface 304 of the substrate 102 since in other embodiments one or more of the feet 510 may be configured for location within a correspondingly shaped area, such as a channel or groove, of the substrate 102. Such an embodiment may improve the attachment of the heat spreader 106 to the substrate 102 and thus provide improved resistance to lateral forces which may cause lateral stresses at the interface between the heat spreader 106 and the substrate 102 during a side gate molding process. However, it will be appreciated that if the feet 510 are located in a groove or channel on the substrate 102 the supports 506 must be sized to allow the clearance D to be established.

Continuing now with reference to FIG. 3, when the heat spreader 106 is attached to the substrate 102, the lower surface 504 of the heat dissipating portion 112 overlies and is spaced apart from an upper surface 302 of the die 104 to provide the clearance D between the lower surface 504 of the heat dissipating portion 112 and the upper surface 302 of the die 104.

The dimension of the clearance D will vary according to package requirements, such as the package thickness or height (H) of the encapsulated die 104 (‘the package’), the material thickness (T) of the heat spreader 106, and the height of the die (h). In the present example, the package thickness H is about 1.15 mm ±0.1 mm, the material thickness T of the heat spreader 106 is about 0.3 mm, and the height of the die 104 is about 0.33 mm. In this example, the clearance D is about 0.52±0.1 mm. Care needs to be taken to ensure that the tolerance of the clearance dimension is not larger than the tolerance of the package thickness H.

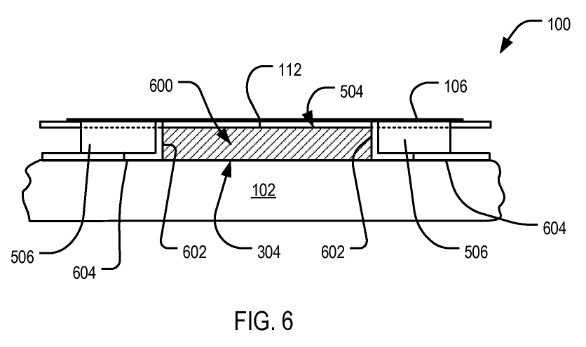

FIG. 6 shows a side view of the semiconductor package 100 viewed along the sectional line C-C′ of FIG. 1 with the encapsulant or molding compound and the die not shown for clarity to assist with the following explanation of the relationship between the heat spreader 106 and the substrate 102.

As shown in FIG. 1 and FIG. 6, attaching the heat spreader 106 to the substrate 102 establishes openings 600 (an example of which is shown in FIG. 6 as a shaded region for clarity) between the supports 506.

As best shown in FIG. 6, each opening 600 is located between, and thus defined by, the lower surface 504 of the heat dissipating portion 112, the substrate 102, and adjacent supports 506. More specifically, in the present case each opening 600 is defined by an edge of the lower surface 504 of the heat dissipating portion 112 which corresponds with the perimeter 402, an area of the upper surface 304 of the substrate 102, and side edges 602 of the adjacent supports 506. As is shown in FIG. 1, at each opening 600, the peripheral or outermost extent of the heat spreader 106 corresponds with the perimeter 402 of the heat dissipating portion 112.

As is evident from FIG. 6, no part of the heat spreader 106 is located on the upper surface 304 of the substrate 102 across the horizontal extent of the opening 600. Indeed, contact between the heat spreader 106 and the substrate 102 is confined to the separate respective attachment areas 604 (ref. FIG. 6) of the supports 506. Thus, the vertical extent of the opening 600 extends between the lower surface 504 (which is a horizontal surface) of the heat dissipating portion 112 and the upper surface 304 (which is also a horizontal surface) of the substrate 102. In other words, the vertical extent of the opening 600 is not obstructed by any part of the heat spreader 106 located on the upper surface 304 of the substrate 102.

The above described arrangement may provide for a larger vertical extent than would otherwise be provided if the opening was formed as a slit or cut-out in a vertical peripheral wall of a prior art heat spreader having a top hat type configuration (i.e. one with a single continuous foot).

Providing the above described openings 600 may allow larger amounts of cleaning gases in and out of the die area and also improve mold flow uniformity. In addition, the openings 600 may permit a lower mold flow rate of mold compound into the die area and thus subject the wire bonds to a reduced flow mold speed, and thus a reduction in wire sweep. The significance of a reduced wire sweep would be understood to a skilled person.

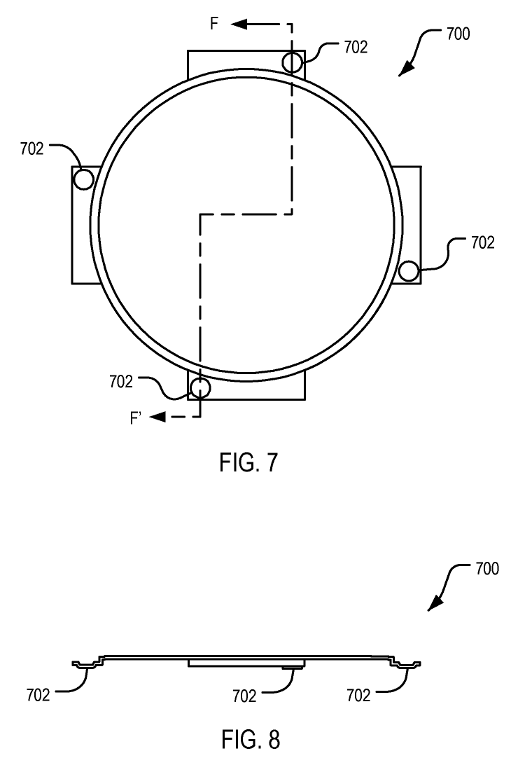

FIG. 7 and FIG. 8 provide a top view and a side view respectively of a heat spreader 700 similar to the heat spreader 106 shown in FIG. 4 and FIG. 5. However, the embodiment depicted in FIG. 7 and FIG. 8 includes downwardly depending projections 702 formed in each foot 510. In this example, the downwardly depending projections 702 are formed during manufacture of the heat spreader 700 using a suitable pressing or stamping tool. The downwardly depending projections 702 may have any suitable shape and/or configuration. Suitable shapes may include a hemispherical shape, a bowl shape, a raised dimple or the like.

In the embodiment illustrated in FIG. 7 and FIG. 8, the projections 702 allow a predictable and repeatable package thickness H (ref. FIG. 3) to be maintained prior to, and after, the heat spreader 700 has been located on and bonded to the substrate 102 at the respective attachment areas 604.

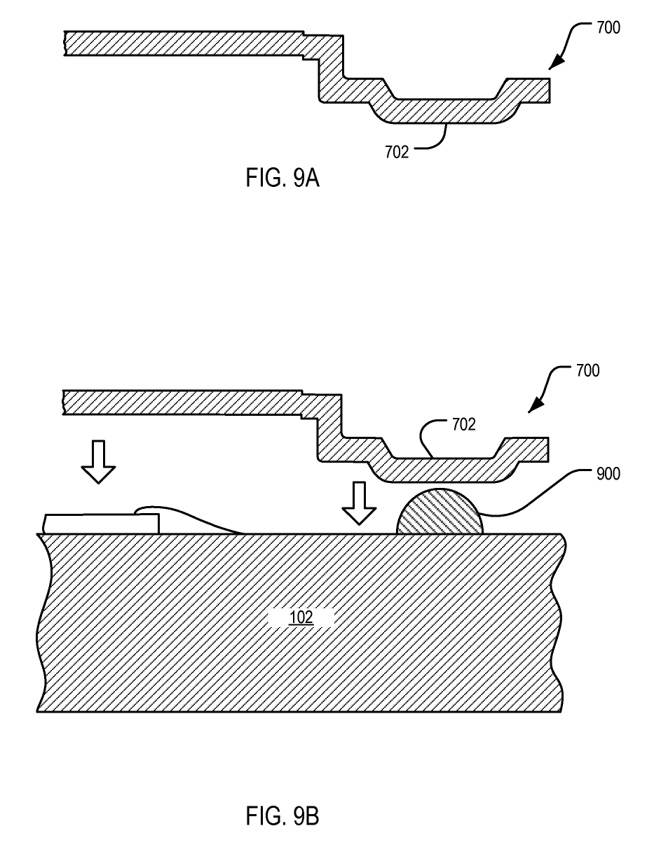

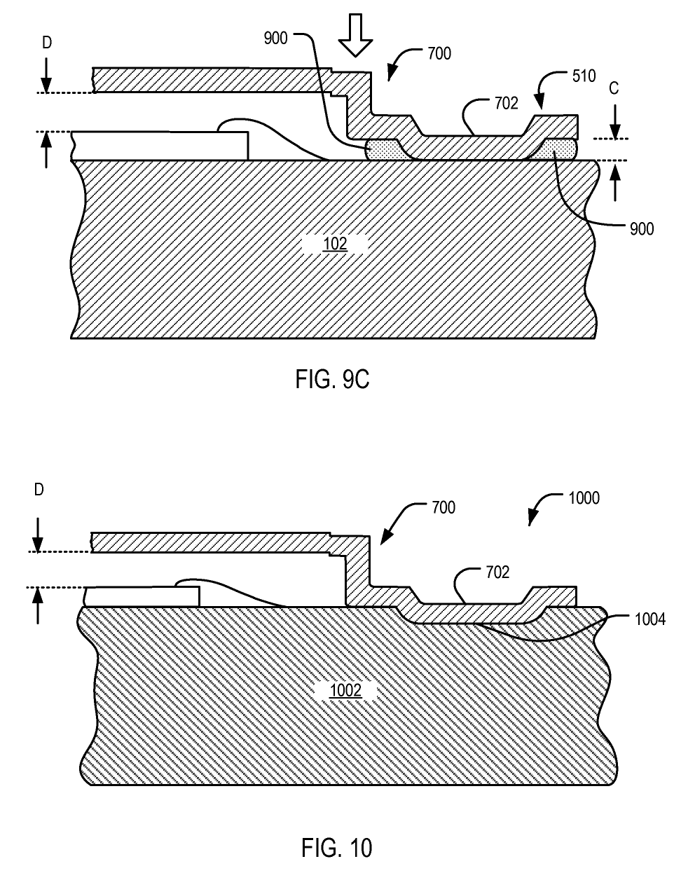

As shown in FIG. 9A to FIG. 9C, the projections 702 are configured to position the heat spreader 700 onto the substrate 102 so that a clearance C (ref. FIG. 9C) is provided between the substrate 102 and the underside of the foot 510. The clearance C provides a space which allows a bonding agent 900 (ref. FIG. 9B), such as an adhesive, to bond the substrate 102 to the underside of the base or foot 510 whilst the projections 702 contact the substrate 102 to thus maintain the predictable and repeatable package thickness H (ref. FIG. 3).

The heat spreader 700 may be attached to the substrate 102 using any suitable process. One suitable process includes dispensing or applying droplets of a suitable bonding agent 900 (ref. FIG. 9B), such as an electrical insulating conductive epoxy resin or a silicone based adhesive, onto the substrate 102 at locations which correspond to areas on the substrate 102 which are intended to interface with the projections 702 (ref. FIG. 7). For example, for the embodiment shown in FIG. 7 the adhesive is applied to the substrate 102 at four positions so that each position matches with the intended position of a respective projection 702.

As shown in FIG. 9B and FIG. 9C, after the adhesive 900 has been applied, the heat spreader 106 is then located on to the substrate 102 using suitable equipment, such as a “pick and place” machine), so that the projections 702 are aligned with the adhesive. In this example, and as is shown in FIG. 9C, locating the heat spreader 106 on the substrate 102 involves pressing the heat spreader 106 onto the substrate 102 with sufficient to force to cause substantially all of the bonding agent 900 to move into the clearance C, so that the projection 702 is located on the substrate 102 with minimal bonding agent 900 therebetween. The resultant package may then be placed in an oven to cure the adhesive.

As will be appreciated, in embodiments that do not include projections 702, it is possible that the heat spreader may “tilt” or “float” during the bonding process since the heat spreader may be separated from the substrate 102 by a layer of the bonding agent, which is typically a liquid layer, prior to curing. Thus, in embodiments without projections 702 the heat spreader may be incorrectly positioned so that it is not flat or co-planar with respect to the substrate 102. Hence, in such embodiments care needs to be taken when bonding the heat spreader to the substrate 102 to ensure that the heat spreader is positioned on and/or aligned with the substrate 102 correctly. In other words, unless care is taken, the heat spreader may “tilt” during the bonding process. Unfortunately, such tilting may cause adhesive to “seep” onto an upper surface of the heat spreader and thus form a defect known to those skilled in the art as ‘mold flash’.

FIG. 10 shows a semiconductor package 1000 in accordance with another embodiment of the present invention. In this example, the substrate 1002 is substantially similar to the substrate 102 shown in FIG. 1 to FIG. 4 except that the substrate 1002 includes four receiving areas 1004. The receiving areas 1004 are configured to mechanically receive the projections 702. In the embodiment illustrated in FIG. 10, the arrangement of the projections 702 and the receiving areas 1004 assist in forming a correct positional relationship between the heat spreader 700 and the substrate 102.

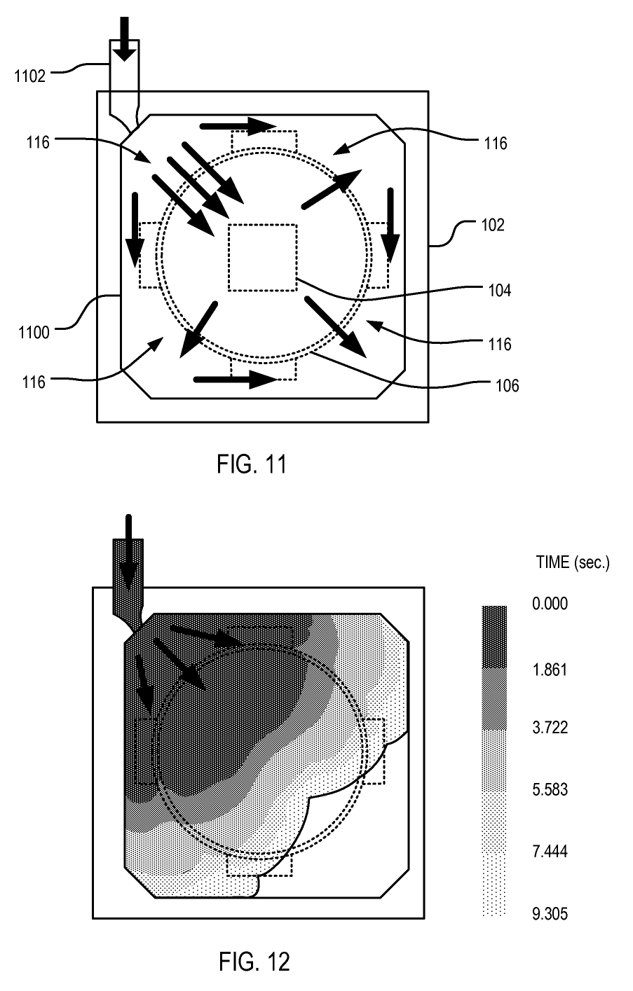

FIGS. 11 and 12 show mold flow diagrams depicting flow paths (represented with arrows in FIG. 11) and flow timing/distribution of the encapsulant 108 during a side gate molding process involving the embodiment depicted in FIGS. 1 to 6.

As shown in FIG. 11, during a side gate molding process, a mold lid 1100 incorporating a gate 1102 for passing the encapsulant material, such as a thermosetting epoxy, is placed over the area of the substrate 102 supporting the die 104 and the heat spreader 106. The encapsulant 108 is then introduced into the mold lid 1100 via the gate so that the encapsulant completely encapsulates the die 104, the supports 506 (ref. FIG. 1) and the lower surface 504 (ref. FIG. 5) of the heat dissipating portion. However, the mold lid 1100 is configured so that that the encapsulant does not cover the upper surface 502 (ref. FIG. 5) of the heat dissipating portion 112. Thus, in this embodiment, the upper surface 502 (ref. FIG. 5) of the heat dissipating portion 112 remains free of encapsulant, and thus exposed, at completion of the molding process.

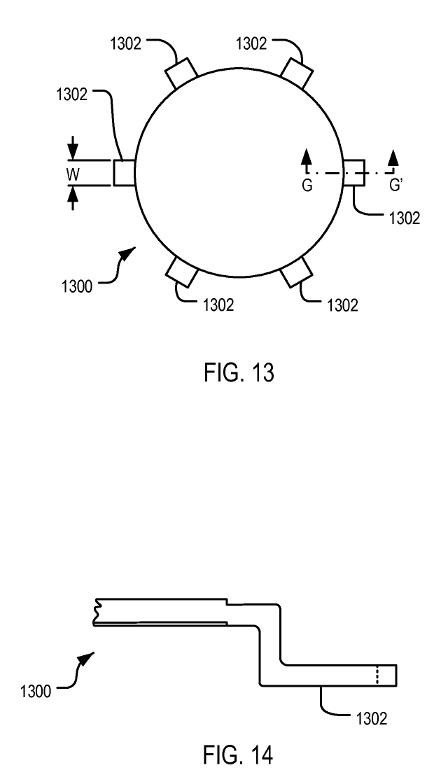

FIG. 13 is a top view and FIG. 14 is an enlarged side view taken along the sectional line G-G′ of FIG. 13 of another embodiment of a heat spreader 1300. The heat spreader 1300 is similar to the heat spreader 106 shown in FIG. 1 to FIG. 6 except that it includes a different number and configuration of spaced apart supports 1302. In this example the spaced apart supports 1302 comprise six projecting tabs having a width (W) of about 1 mm. It will of course be appreciated that width of the spaced apart supports 1302 may vary for different package sizes and thus other widths may be used.

Embodiments of the present invention are expected to permit a reduced contact angle during pre-encapsulation cleaning, and a reduced wire sweep angle during the encapsulation process. In terms of the reduced contact angle, and as will be appreciated by a skilled reader, after the heat spreader 106/700 has been attached to the substrate 102, but prior to encapsulation, the surface of the die 104 is typically cleaned to remove impurities and contaminants using a suitable cleaning process, such as a gaseous cleaning process involving plasma cleaning. The configuration of the openings 600 may reduce obstructions to plasma gas flow though the openings 600 and thus may permit embodiments of the present invention to allow a larger amount of plasma gas to enter the openings and thus provide for more effective cleaning of the die surface.

Finally, it is to be understood that various alterations, modifications and/or additions may be introduced into the constructions and arrangements of parts previously described without departing from the spirit or ambit of the invention.

1. A semiconductor package, comprising:
a substrate;
a die attached to the substrate; and
a heat spreader, the heat spreader comprising:
a heat dissipating portion having an upper surface, a lower surface and a perimeter, the lower surface overlying and spaced apart from the die to provide a clearance therebetween; and
plural supports spaced about the perimeter of the heat dissipating portion and depending downwardly therefrom, wherein each support is located on the substrate to establish an opening between adjacent supports.

2. A semiconductor package according to claim 1, wherein a molding compound fills the clearance and encapsulates the die.

3. A semiconductor package according to claim 2, wherein the substrate comprises a plastic ball grid array.

4. A semiconductor package according to claim 1, wherein each opening has a vertical extent extending between the lower surface of the heat dissipating portion and the substrate, and a horizontal extent extending between opposite side edges of adjacent supports.

5. A semiconductor package according to claim 4, wherein the vertical extent and the horizontal extent of the opening are sized for flow therethough of a molding compound for filling the clearance and encapsulating the die.

6. A semiconductor package according to claim 1, wherein the heat spreader further comprises a plurality of feet and each support is located on the substrate by means of one or more of the feet.

7. A semiconductor package according 6, wherein each foot includes an underside surface and means for establishing a clearance between the underside surface and the substrate for accommodating a bonding agent.

8. A semiconductor package according 7, wherein the means for establishing a clearance includes at least one projection.

9. A semiconductor package according to claim 8, wherein the projection includes a hemispherical projection.

10. A semiconductor package according to claim 1, wherein each support subtends at a central angle δ about a respective extent of the perimeter of the heat dissipating portion, and wherein each opening subtends at a central angle θ about a respective extent of the perimeter that is substantially the same as or greater than the central angle δ.

11. A semiconductor package according to claim 1, wherein the lower surface of the heat dissipating portion comprises a substantially planar surface.

12. A plastic ball grid array semiconductor package, comprising:
a substrate;
a die attached to the substrate; and
a heat spreader comprising:
a heat dissipating portion comprising an upper surface, a lower surface and a perimeter, the lower surface overlying and spaced apart from the die to provide a clearance therebetween; and
plural supports spaced about the perimeter of the heat dissipating portion and depending downwardly thereof, wherein each support is located on the substrate to establish an opening between adjacent supports;
wherein each opening has a vertical extent extending between the lower surface of the heat dissipating portion and the substrate, and a horizontal extent extending between opposite side edges of the adjacent supports, and wherein the vertical extent and the horizontal extent of the openings are adapted for flow therethough of a molding compound, said molding compound for filling the clearance and encapsulating the die.

13. A plastic ball grid array semiconductor package according to claim 12, wherein the molding compound fills the clearance and encapsulates the die.

14. A plastic ball grid array semiconductor package according to claim 12 wherein each support is located on the substrate by means of a foot.

15. A plastic ball grid array semiconductor package according 14, wherein each foot includes an underside surface and means for establishing a clearance between the underside surface and the substrate for accommodating a bonding agent.

16. A plastic ball grid array semiconductor package according 15, wherein the means for establishing a clearance includes at least one projection.

17. A plastic ball grid array semiconductor package according to claim 16, wherein the at least one projection includes a hemispherical projection.

18. A plastic ball grid array semiconductor package according to claim 12, wherein each support subtends a central angle δ about a respective extent of the perimeter of the heat dissipating portion, and wherein each opening subtends a central angle θ about a respective extent of the perimeter which is substantially the same as or greater than the central angle δ.

19. A heat spreader for attaching to a substrate of a semiconductor package, the heat spreader comprising:
a heat dissipating portion comprising an upper surface, a lower surface and a perimeter; and
plural supports spaced about the perimeter of the heat dissipating portion and depending downwardly therefrom;
wherein each support is adapted to locate the heat spreader on the substrate establish an opening between adjacent supports, such that each opening has a vertical extent extending between the lower surface of the heat dissipating portion and the substrate and a horizontal extent extending between opposite side edges of the adjacent supports, and wherein the vertical extent and the horizontal extent of the openings are adapted for flow therethough of a molding compound, said molding compound for filling the clearance and encapsulating the die.

20. A heat spreader according to claim 19, wherein each support is arranged for location on the substrate by means of a foot, wherein the foot includes an underside surface and means for establishing a clearance between the underside surface and the substrate for accommodating a bonding agent.
